(19) United States
(12) Patent Application Publication
(10) Pub. No.: US 2026/0094596 A1
(43) Pub. Date: Apr. 2, 2026

(54) BROADBAND ACOUSTIC METASURFACE

(71) Applicant: AMD Design, LLC, Wilmington, DE (US)

(72) Inventors: Darrin Troy VALLIS, Austin, TX (US); Paul Cameron MERCER, Fairlawn, NJ (US)

(73) Assignee: AMD Design, LLC, Wilmington, DE (US)

(21) Appl. No.: 19/337,062

(22) Filed: Sep. 23, 2025

Related U.S. Application Data
(60) Provisional application No. 63/701,993, filed on Oct. 1, 2024.

(51) Int. Cl. G10K 11/175; G10K 11/178; H05K 7/20

(52) U.S. Cl. CPC G10K 11/1752; G10K 11/1781; H05K 7/20136; H05K 7/20718

(57) ABSTRACT

The broadband acoustic metasurface is configured to be disposed in or around a server and includes a body forming a plurality of chambers having respective volumes. The body also forms a plurality of holes in communication with the chambers that are configured to be in communication with moving air within or around the server. Floors of the chambers may be configured to move via a plurality of actuators to adjust the volumes of the chambers. The actuators may be controlled by a processing unit that is configured to determine the volumes for the chambers and cause the actuators to adjust the volumes of the chambers to the determined volumes. The chambers are configured to attenuate sound through destructive interference, where the volumes of the chambers correspond to respective target frequencies to attenuate. By using adjacent chambers with different volumes, broadband attenuation may be achieved in a space efficient manner.

### RELATED APPLICATIONS

This application claims priority to U.S. Provisional Application 63/701,993, filed Oct. 1, 2024, the entire disclosure of which is incorporated herein by reference.

### FIELD

This disclosure is directed to sound reduction in and/or around servers.

### BACKGROUND

Servers often utilize fans to draw air around/through components within the servers to mitigate heat generated by the components. Even in water-cooled servers, fans are used to mitigate heat generated by secondary components within the servers (e.g., components other than processing systems or in conjunction with water-cooling systems).

Modern servers (e.g., cloud-computing servers, artificial intelligence (AI) and/or machine learning (ML) servers, networking servers, block-chain servers, storage servers, etc.) are performing more tasks than ever before, and, as such, are also generating more heat than ever before. To compensate for the increased heat, airflow requirements have also increased. Increased airflows often means increased noise from the fans and/or from the air moving through the servers.

Further compounding the noise problem is the sheer number of servers that are often collocated. So called “server farms” can contain thousands of servers with compounding noise problems. Noise in such environments is often unwieldy (e.g., require cumbersome hearing protection) and can also negatively affect neighboring rooms (e.g., offices).

All of the subject matter discussed in this section is not necessarily prior art and should not be assumed to be prior art merely as a result of its discussion in this section. Along these lines, any recognition of problems in the prior art discussed in this section or associated with such subject matter should not be treated as prior art unless expressly stated to be prior art. Instead, the discussion of any subject matter in this section should be treated as part of the inventor's approach to the particular problem, which, in and of itself, may also be inventive.

### SUMMARY

Described herein is broadband acoustic metasurface for a server. The broadband acoustic metasurface may be an apparatus configured to be disposed within or proximate the server. The broadband acoustic metasurface includes a body forming a plurality of chambers having respective volumes and a plurality of holes in communication with the chambers and configured to be in communication with moving air within or around the server.

Also described herein is a system including the broadband acoustic metasurface and a plurality of actuators configured to move floors of the chambers along respective longitudinal axes of the chambers.

Further described herein is a system including a processing unit configured to determine heights of the chambers of the broadband acoustic metasurface and cause one or more actuators to position floors of the broadband acoustic metasurface such that that the chambers assume the determined heights.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

Non-limiting and non-exhaustive embodiments are described with reference to the following drawings, wherein like labels refer to like parts throughout the various views unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings. One or more embodiments are described hereinafter with reference to the accompanying drawings.

FIG. 1 illustrates an example of a server with a plurality of broadband acoustic metasurfaces installed therein.

FIG. 2A illustrates an example of a broadband acoustic metasurface.

FIG. 2B illustrates a section of the broadband acoustic metasurface of FIG. 2A.

FIG. 3 illustrates another example of a broadband acoustic metasurface.

FIG. 4 illustrates another example of a broadband acoustic metasurface.

FIG. 5A illustrates an example of a cell of a broadband acoustic metasurface.

FIG. 5B illustrates a section of the cell of FIG. 5A.

FIG. 6 illustrates another example of a cell of a broadband acoustic metasurface.

FIG. 7 illustrates another example of a cell of a broadband acoustic metasurface.

FIG. 8A illustrates another example of a cell of a broadband acoustic metasurface.

FIG. 8B illustrates a section of the cell of FIG. 8A.

FIG. 9A illustrates another example of a cell of a broadband acoustic metasurface that is similar to the cell of FIGS. 8A and 8B but with a different floor height.

FIG. 9B illustrates a section of the cell of FIG. 9A.

FIG. 10A illustrates another example of a cell of a broadband acoustic metasurface that is similar to the cell of FIGS. 8A and 8B but with a different overall height.

FIG. 10B illustrates a section of the cell of FIG. 10A.

FIG. 11 illustrates an example system that may be used to configure a broadband acoustic metasurface.

FIG. 11 illustrates an example of a cell of a broadband acoustic metasurface with an actuator configured to move a floor height of the cell.

FIG. 12 illustrates an example of a cell of a broadband acoustic metasurface with an actuator configured to move a floor of the cell.

FIG. 13 illustrates an example of cells of a broadband acoustic metasurface with an actuator configured to move floors of the cells together.

FIG. 14 illustrates an example flow of configuring chamber heights of a plurality of cells of a broadband acoustic metasurface.

FIG. 15 illustrates an example system that may be used to configure chamber heights of a broadband acoustic metasurface.

### DETAILED DESCRIPTION

### Overview

Modem servers (e.g., cloud-computing servers, artificial intelligence (AI) and/or machine learning (ML) servers, networking servers, block-chain servers, storage servers, etc.) are performing more tasks than ever before, and, as such, are also generating more heat than ever before. To compensate for the increased heat, airflows through such servers have also increased. Even water-cooled servers often require fans to move air through/around components. The airflow requirements have led to increased noise from the fans and/or from turbulences generated by the airflows. The noise issue is often compounded by large numbers of servers being collocated.

Conventional techniques of noise mitigation (e.g., implementing air cells, modifying intake and/or exit grills, removing flaps from fans, placing vent holes within chassis of the servers, adding foam or other sound absorption materials, removing finger guards, different blade/fan designs, etc.) are often only marginally effective in reducing sound levels. Furthermore, many conventional techniques come with drawbacks such as decreased server performance, large space consumption, decreased safety, and others.

Described herein is broadband acoustic metasurface for a server. The broadband acoustic metasurface may be an apparatus configured to be disposed within or proximate the server. The broadband acoustic metasurface includes a body forming a plurality of chambers having respective volumes. The body also forms a plurality of holes in communication with the chambers that are configured to be in communication with moving air within or around the server. Floors of the chambers may be configured to move via a plurality of actuators to adjust the volumes of the chambers. The actuators may be controlled by a processing unit that is configured to determine the volumes for the chambers and cause the actuators to adjust the volumes of the chambers to the determined volumes. The chambers are configured to attenuate sound through destructive interference, where the volumes of the chambers correspond to respective target frequencies to attenuate.

By using adjacent chambers with different volumes, broadband attenuation may be achieved in a space efficient manner. Doing so may mitigate noise with very little negative impact on server operation. Furthermore, when implemented within many collocated servers, noise levels may be dramatically reduced.

The present disclosure may be understood more readily by reference to this detailed description and the accompanying figures. The terminology used herein is for the purpose of describing specific embodiments only and is not limiting to the claims unless a court or accepted body of competent jurisdiction determines that such terminology is limiting. Unless specifically defined in the present disclosure, the terminology used herein is to be given its traditional meaning as known in the relevant art.

In the following description, certain specific details are set forth in order to provide a thorough understanding of various disclosed embodiments. However, one skilled in the relevant art will recognize that embodiments may be practiced without one or more of these specific details, or with other methods, components, materials, etc. Also in these instances, well-known structures may be omitted or shown and described in reduced detail to avoid unnecessarily obscuring more detailed descriptions of the embodiments.

### Example Server

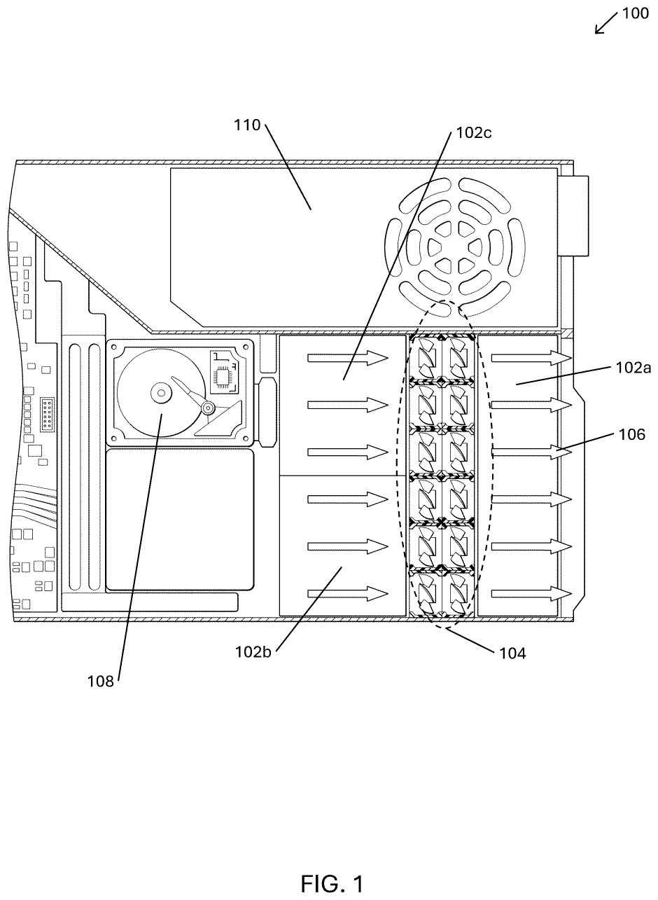

FIG. 1 illustrates an example of server 100 with a plurality of broadband acoustic metasurfaces 102 (e.g., broadband acoustic metasurface 102a, broadband acoustic metasurface 102b, and broadband acoustic metasurface 102c) installed therein. The broadband acoustic metasurfaces 102 may also be referred to as broadband acoustic attenuators, dampers, dampeners, cancellers, filters, deadeners, mitigators, and the like. Similarly, the broadband acoustic metasurfaces 102 may be considered as metamaterials, variable frequency acoustic metasurfaces, tightly packed acoustic metasurfaces, optimally packed acoustic metasurfaces, spatially-tuned broadband acoustic metasurfaces, adaptive acoustic metasurfaces, dynamic acoustic metasurfaces, or variable frequency acoustic metasurfaces. Broadband, as used herein, refers to a plurality of attenuation frequencies/bands.

Although three of the broadband acoustic metasurfaces 102 are shown, the server 100 may include any number of broadband acoustic metasurfaces 102 (e.g., more or less than three). Furthermore, the locations of the broadband acoustic metasurfaces 102 may vary without departing from the scope of this disclosure. For example, although the broadband acoustic metasurfaces 102 are shown within a footprint of the server 100 (e.g., on or near the floor of the server 100), one or more of the broadband acoustic metasurfaces 102 may be mounted to a ceiling, cover, and/or lid of the server 100 and/or walls of the server 100. A ceiling-mount may be advantageous as there are usually not many components mounted to the ceiling/cover of the server 100. Furthermore, one or more of the broadband acoustic metasurfaces may be disposed external to the server 100 (e.g., mounted to an outside of a chassis of the server 100, mounted within a hot or cold aisle (e.g., to a door or wall of the hot or cold aisle) proximate the server, to a server rack, etc.).

The broadband acoustic metasurfaces 102, individually or in conjunction, may take any of the configurations discussed below and/or be tuned for respective sets of frequencies/frequency bands. In other words, the broadband acoustic metasurfaces 102 may be configured for frequencies, to accommodate packaging requirements, for installation locations within or outside of the server 100, and other factors.

The server 100 includes a plurality of fans 104 configured to create a moving airflow 106 through the server 100. For example, the fans 104 may be configured to draw air from a “cold aisle” or other source, cause the air to flow through/around components within the server 100, and exhaust the air to a “warm aisle” or other heat sink. Although the airflow 106 is shown as left to right, the airflow 106 may be right to left, up to down, down to up, or any other configuration. The fans 104 may be in any configuration (e.g., differently sized, dispersed, adjacent to one another, facing other directions than shown, etc.) and in any number (e.g., a single fan or more or less fans than illustrated). Regardless of configuration of the server, the airflow 106 moves through the server 100.

Noise may be generated by the fans 104 themselves (e.g., blades of the fans 104, motors of the fan 104) and/or from the airflow 106 moving through the server 100 (e.g., turbulence in and around components). Furthermore, noise may be generated by air entering or exiting the server 100. It should also be noted that the broadband acoustic metasurfaces 102 may effectively attenuate sound even if the airflow 106 does not exist. For example, the broadband acoustic metasurfaces 102 may cancel sound waves from adjacent areas (e.g., other servers) even if the fans 104 are not operating and/or if there is no air moving through the server 100. In general, however, the broadband acoustic metasurfaces 102 may be proximate sources of the noise they are configured to attenuate.

A broadband acoustic metasurface 102 may be configured to attenuate frequencies depending upon location, target frequencies, neighboring components, etc. To do so, the broadband acoustic metasurface 102 includes a body forming a plurality of cells, with each cell tuned to a certain attenuation frequency. As discussed below, groups of cells may share an attenuation frequency. Thus, the broadband acoustic metasurface 102 includes a plurality of groups of cells, with each group including one or more cells.

As an example, the broadband acoustic metasurface 102a may be disposed proximate outlets of the fans 104 (e.g., in an outlet flow area of the fans 104, on an exhaust side of the fans 104, on a positive pressure side of the fans 104, etc.) and may be configured to attenuate frequencies associated with that area. The broadband acoustic metasurface 102a may be tuned to attenuate m number of frequencies/ranges using m groups of cells. The groups may have one or more dimensions that are different from others to cause the cells of the respective groups to attenuate different target frequencies/ranges.

As another example, the broadband acoustic metasurface 102b may be disposed proximate intakes of the fans 104 (e.g., within an intake flow area of the fans 104, on an inlet side of the fans 104, on a negative pressure side of the fans 104, etc.) and may be configured to attenuate frequencies/ranges associated with that area. The broadband acoustic metasurface 102b may be tuned to attenuate n number of frequencies/ranges using n groups of cells. The groups may have one or more dimensions that are different from others to cause the cells of the respective groups to attenuate different target frequencies/ranges.

Certain frequencies of noise may cause a component 108 (e.g., a hard disk drive, memory, etc.) of the server 100 to not perform properly (e.g., cause missed reads and/or writes). Such problems may be caused by vibrations, resonant frequencies, and other issues related to the noise. To mitigate such noise, as another example, the broadband acoustic metasurface 102c may be configured to attenuate frequencies that are problematic for the component 108 (instead of or in addition to frequencies associated with the intake side of the fans 104). The broadband acoustic metasurface 102c may be placed between the fans 104 and the component 108. It should be noted that, even though the airflow is going away from the component 108, sound may still travel back to the component 108.

The broadband acoustic metasurface 102c may be tuned to attenuate any number of frequencies/ranges associated with the component 108 and/or intake side fan noise (e.g., via respective groups of cells). For example, the broadband acoustic metasurface 102c may be tuned to attenuate o number of frequencies/ranges using o groups of cells. The groups may have one or more dimensions that are different from others to cause the cells of the respective groups to attenuate different target frequencies.

It should be noted that broadband acoustic metasurfaces 102 may be combined or divided into any number of structures to make any number of groups and/or cells. For example, broadband acoustic metasurfaces 102b and 102c may be formed by a single structure with one or more groups configured to attenuate noise associated with the component 108 and one or more other groups configured to attenuate noise associated with the intake side of the fans 104. In some cases, the target frequencies may overlap. Furthermore, the broadband acoustic metasurfaces 102a, 102b, and 102c may all be part of a single component with the fans 104 (or other component(s)) placed thereon.

Broadband acoustic metasurfaces 102 may be placed anywhere within and/or around the server 100 and may be tuned for any number of frequencies/ranges. As another example, certain frequencies may affect operations of random-access memory (RAM) or other memory systems and, thus, a broadband acoustic metasurface 102 may be placed proximate a RAM or memory module and may be tuned to attenuate those detrimental frequencies. As yet another example, a PSU 110 (e.g., power supply unit) may generate noise. Accordingly, a broadband acoustic metasurface 102 may be placed proximate or even within the PSU 110 to attenuate frequencies associated with the PSU 110. As a further example, a broadband acoustic metasurface 102 may be placed proximate an intake or exhaust grate/port of the server 100 to attenuate frequencies associated with the intake or exhaust grate. It should be noted, however, that a broadband acoustic metasurface 102 need not be proximate a noise source. In other words, a broadband acoustic metasurface 102 may be placed remote to a source of noise it is configured to attenuate as long as the noise still exists at the location of the broadband acoustic metasurface 102.

### Examples Broadband Acoustic Metasurfaces

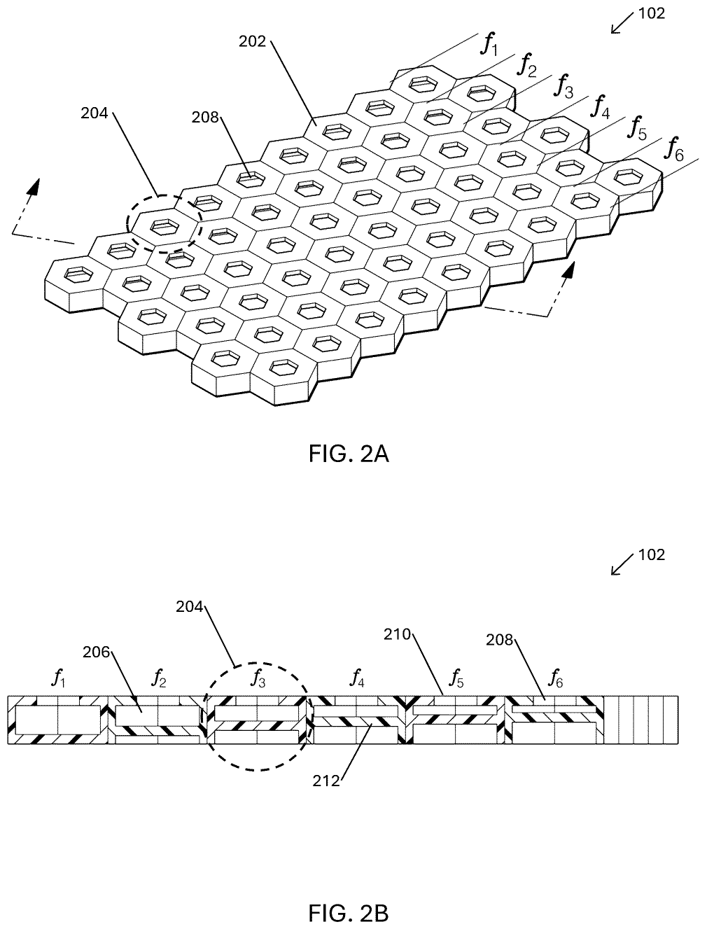

Referring to FIGS. 2A-4, examples of the broadband acoustic metasurfaces 102 are described. Not all of the following components are labeled in each of FIGS. 2A-4. Each of the broadband acoustic metasurfaces 102 includes a body 202 that forms a plurality of cells 204. Each of the cells 204 is part of a group of one or more cells that are configured to attenuate a certain frequency/range. Although single attenuation frequencies are used herein, it should be noted that each cell will attenuate a range of frequencies centered around its attenuation frequency. The broadband acoustic metasurfaces 102 may be configured to attenuate frequencies ranging between 0 and 12,000 Hz, with any number of target attenuation frequencies therein. Other frequencies and frequency ranges have of course been contemplated.

The body 202 may be formed of metal, plastic, or any other suitable material and may be 3D printed, injection molded (as one or more components), cast, or produced via any other suitable manufacturing processes. The body 202 may be formed by individually formed cells that are connected or otherwise placed adjacent to each other or as a single structure (e.g., which forms the cells 204). For example, although FIGS. 2A-4 show lines dividing the cells 204 (e.g., alluding to individually formed cells), such lines may not exist if the body 202 is formed as a single structure. If the body 202 is formed as a single structure, then the cell divisions may be non-physical and within walls shared by adjacent cells. Accordingly, a top of the body 202 and/or cross sections may have no dividing lines.

The cells 204 form chambers 206 and holes 208 which are in communication with the chambers 206. The holes 208 may be considered necks of the chambers 206. Ends of the holes 208 opposite the chambers 206 are referred to as open ends 210. The open ends 210 may be configured to be in contact with the airflow 106. The chambers 206 and the holes 208, together, form respective Helmholtz resonators. Thus, each broadband acoustic metasurface 102 includes multiple Helmholtz resonators which form a broadband acoustic attenuator. The cells 204 are spatially compressed, thereby realizing a small form factor.

It should be noted that the open ends 210 need not be in direct contact with the airflow 106 to enable the broadband acoustic metasurfaces to function. Although better noise mitigation may be achieved when the open ends 210 are proximate the airflow 106, because sound carries through air, the broadband acoustic metasurfaces may function with the open ends 210 disposed anywhere where noise is present.

The broadband acoustic metasurface 102 contains a plurality of groups of one or more cells 204, with each group including cells 204 configured to attenuate a unique frequency. The groups may be defined by zones of the broadband acoustic metasurface 102. Any number of groups having any number of cells 204 (and different numbers between the groups) may be implemented. Cells 204 of a group may be interspersed amongst cells 204 belonging to one or more other groups. In other words, one or more chambers 206 belonging to a first group may be interspersed amongst chambers 206 belonging to a second group. Furthermore, groups may take any shape within the broadband acoustic metasurface 102. Although FIGS. 2-4 show cells 204 with the same footprints, cells 204 of one group may be different than cells 204 of a different group. It should be noted, however, that having similar footprints among the different groups may facilitate better space utilization.

At least one of the groups may be arranged in a linear array. As an example configuration, FIG. 2 shows groups comprising rows (or columns) of cells 204 that are configured for respective frequencies f. For example, the top left row may be tuned for a frequency f₁, and the bottom right row may be tuned for a frequency f₆.

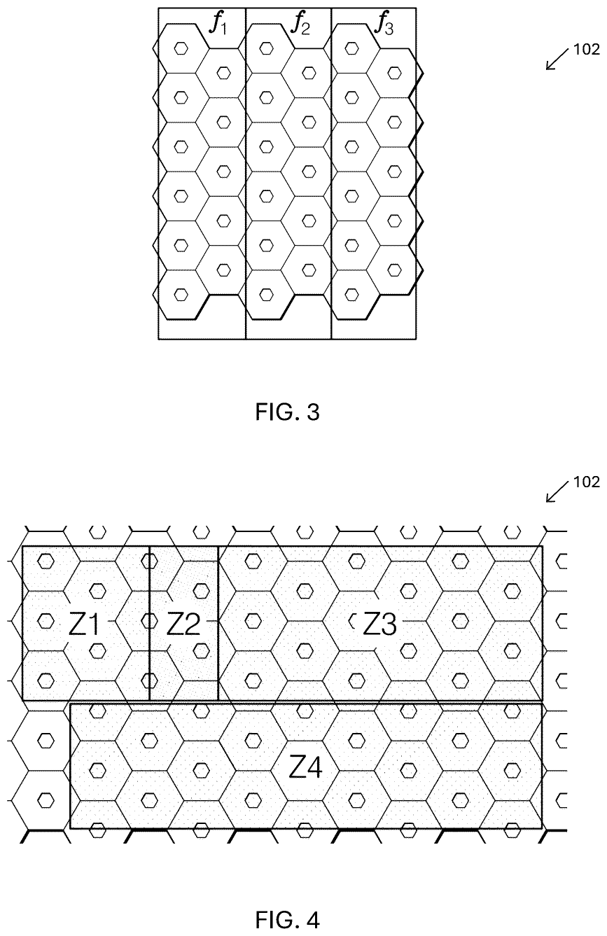

At least one of the groups may also be arranged in a two-dimensional array. The example of FIG. 3 is similar to that of FIG. 2, however, each group has two rows of cells 204. For example, the left two rows may be tuned for a frequency f₁, and the right two rows may be tuned for a frequency f₃. FIG. 4 shows groups comprising blocks of cells 204 that are configured for respective frequencies f. For example, the Z1 group may be tuned for a frequency f₁, and the Z4 group may be tuned for a frequency f₄.

Dimensions of the chambers 206 and the holes 208 dictate frequency attenuation of the cells 204. For example, a cell 204 may be configured to attenuate a frequency fᵣ according to Equation 1:

$${f}_{r} = \frac{{v}_{s}}{2 π} \sqrt{\frac{a}{{Vl}_{eq}}} \qquad ( 1 )$$

where vₛ is the speed of sound in the applicable gas (e.g., air in most implementations within or around the server 100), a is the cross-sectional area of the hole 208, V is the volume of the chamber 206, l_{eq} is the equivalent length of the hole 208 with end correction (e.g., l+δ, where l is the length of the hole 208 and δ is an end correction factor

$$( e . g . , \frac{0.27 A}{\sqrt{a}} ,$$

where A is the cross-sectional area of the chamber 206 and a is the cross-sectional area of the hole 208)).

Looking at FIG. 2B, the groups of cells 204 (e.g., rows) are differentiated via different distances between floors 212 of the cells 204 and the holes 208. In other words, chamber heights of the chambers 206 are varied across the groups with the other dimensions staying constant. As such, V also varies across the rows which varies the attenuation frequency. Since V=AH for a columnar or cylindrical chambers, where A is the cross-sectional area of the chamber and H is the height of the chamber, Equation 1 may be solved for H to give Equation 2:

$$H = \frac{{av}_{s}^{2}}{4 {π}^{2} {Af}_{r}^{2} ( l + 0.27 \frac{A}{\sqrt{a}} )} \qquad ( 2 )$$

Thus, Equation 2 may be used to determine heights of the chambers 206 for respective attenuation frequencies. Assuming the other dimensions of the chambers 206 and the holes 208 stay the same, a larger height H will result in a lower attenuation frequency, and a smaller height H will result in a higher attenuation frequency. Varying the height of the chambers 206 while keeping the other dimensions of the cells 204 constant enables efficient space utilization and easy calculation/variation of attenuation frequency. Furthermore, manufacturing may be simplified. It should be noted, however, that other dimensions may be varied between the groups of cells 204, alternatively or in conjunction with the height of the chambers 206, to vary attenuation frequencies.

### Example Cells

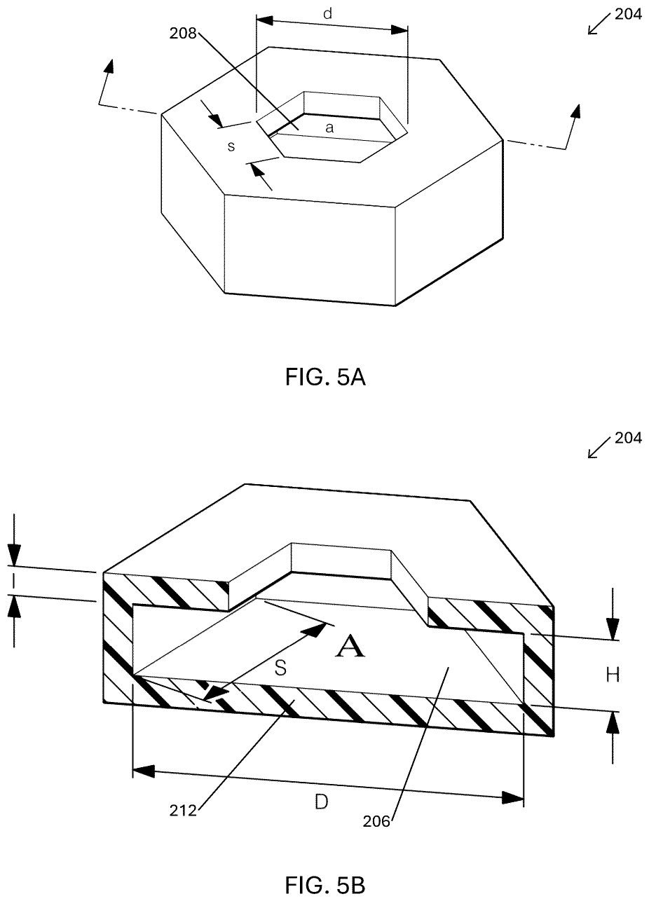

FIGS. 5A-7 show examples of the cell 204. As discussed above, the cell 204 may be formed together with one or more adjacent cells as part of the body 202 or as a stand-alone cell that is joined with other cells 204 to form the body 202. Regardless of how the cell 204 is formed, the dimensions of the chamber 206 and the hole 208 determine the attenuation frequency of the cell 204.

FIG. 5A illustrates an example of the cell 204. FIG. 5B is a cross section of the cell 204 of FIG. 5A. The chamber 206 and the hole 208 are configured as hexagonal columns. In other words, the chamber 206 has a polygonal cross-section along a longitudinal axis of the chamber 206. The hexagonal-shaped chamber may allow for tight placement of adjacent chambers (within the same group or another group) to thereby optimize packing of the cells forming the broadband acoustic metasurface 102. The hexagonal-shaped hole may allow for easier calculations.

To determine a relationship between a chamber height Hand the attenuation frequency fᵣ, Equation 2 may be used with

$$a = \frac{3 \sqrt{3}}{2} {S}^{2} ,$$

where s is the length of a flat of the hole 208, and

$$A = \frac{3 \sqrt{3}}{2} {S}^{2} ,$$

where S is the length of a flat of the chamber 206, to arrive at Equation 3:

$$H = \frac{{s}^{2} {v}_{s}^{2}}{4 \sqrt{3} {π}^{2} {S}^{2} {f}_{r}^{2} ( l + 0.27 \frac{\frac{3 \sqrt{3}}{2} {S}^{2}}{\sqrt{\frac{3 \sqrt{3}}{2} {s}^{2}}} )} \qquad ( 3 )$$

Therefore, given a plurality of target attenuation frequencies, a plurality of chamber heights H may be determined for a plurality of cells 204 configured with chambers 206 and holes 208 having hexagonal cross-sections. Although not required, it may be assumed that the other dimensions (e.g., other than chamber height H) remain constant between the cells 204.

Assuming dimensions are in inches and the speed of sound is in feet per second squared, H may also be given according to Equation 4:

$$H = \frac{144 {d}^{2}}{{( \frac{2 π fr}{{v}_{s}} )}^{2} {D}^{2} ( l + δ )} \qquad ( 4 )$$

As an example of broadband attenuation, assume that dis 0.5 inches, l is 0.080 inches, D is 1 inch, and the overall height of the cell is such that a maximum chamber height His 0.260 inches, which corresponds to a 3000 Hz attenuation frequency. To attenuate a 6000 Hz wave, H is calculated to be 0.065 inches. To attenuate a 7000 Hz wave, His calculated to be 0.048 inches. It should be noted that a taller overall height may be used to achieve attenuation of a lower frequency (e.g., a 2000 Hz wave would require a 0.584 inch chamber height H). Thus, to achieve broadband attenuation (e.g., between 3000 Hz and 7000 Hz), the chamber heights may be varied between 0.260 and 0.048. Attenuation of other frequencies and frequency ranges, and corresponding other chamber heights, have of course been contemplated.

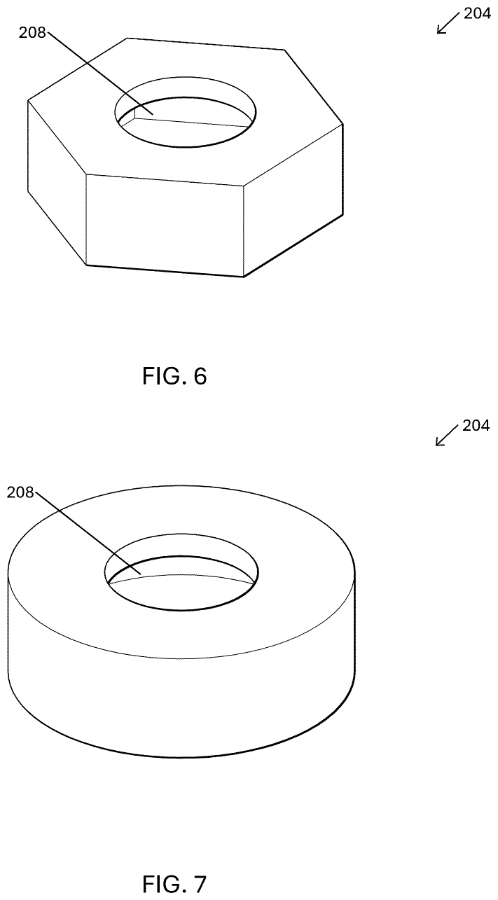

FIG. 6 illustrates another example of a cell 204. The illustrated example is similar to that of FIGS. 5A and 5B; however, the hole 208 is circular instead of hexagonal. To determine the relationship between the chamber height H for the cell 204 and the attenuation frequency fᵣ, Equation 2 may be used with

$$a = \frac{π {d}^{2}}{4} ,$$

where d is the diameter of the hole 208, and

$$A = \frac{3 \sqrt{3}}{2} {S}^{2} ,$$

where S is the length of a flat of the chamber 206, to arrive at Equation 5:

$$H = \frac{{d}^{2} {v}_{s}^{2}}{24 \sqrt{3} {πS}^{2} {f}_{r}^{2} ( l + 0.27 \frac{\frac{3 \sqrt{3}}{2} {S}^{2}}{\sqrt{\frac{π {d}^{2}}{4}}} )} \qquad ( 5 )$$

Therefore, given a plurality of target attenuation frequencies, a plurality of chamber heights H may be determined for a plurality of cells 204 configured with hexagonal chambers and round holes. Although not required, it may be assumed that the other dimensions (e.g., other than height H) remain constant between the cells 204.

FIG. 7 illustrates another example of a cell 204. The illustrated example has a cylindrical chamber and a round hole. To determine the relationship between the chamber height H for the cell 204 and the attenuation frequency fᵣ, Equation 2 may be used with

$$a = \frac{π {d}^{2}}{4} ,$$

where d is the diameter of the hole 208, and

$$A = \frac{3 \sqrt{3}}{2} {S}^{2} ,$$

where S is the length of a flat of the chamber 206, to arrive at Equation 6:

$$H = \frac{{d}^{2} {v}_{s}^{2}}{16 π {D}^{2} {f}_{r}^{2} ( l + 0.27 \frac{\frac{π {D}^{2}}{4}}{\sqrt{\frac{π {d}^{2}}{4}}} )} \qquad ( 6 )$$

Therefore, given a plurality of target attenuation frequencies, a plurality of chamber heights H may be determined for a plurality of cells 204 configured with round chambers and round holes. Although not required, it may be assumed that the other dimensions (e.g., other than chamber height H) remain constant between the cells 204.

Although not illustrated, the cell 204 may also have a triangular chamber with a round hole. In such cases, the relationship between chamber height Hand the attenuation frequency fᵣ may be given according to Equation 7:

$$H = \frac{{d}^{2} {v}_{s}^{2}}{4 \sqrt{3} {πS}^{2} {f}_{r}^{2} ( l + 0.27 \frac{\frac{\sqrt{3} {S}^{2}}{4}}{\sqrt{\frac{π {d}^{2}}{4}}} )} \qquad ( 7 )$$

where S is a length of a side of the chamber 206 and d is the diameter of the hole 208.

Also not illustrated, the cell 204 may also have a rectangular chamber with a round hole. In such cases, the relationship between chamber height Hand the attenuation frequency fᵣ may be given according to Equation 8:

$$H = \frac{{d}^{2} {v}_{s}^{2}}{16 π {S}^{2} {f}_{r}^{2} ( l + 0.27 \frac{{S}^{2}}{\sqrt{\frac{π {d}^{2}}{4}}} )} \qquad ( 8 )$$

where S is a length of a side of the chamber 206 and d is the diameter of the hole 208.

Other cross section shapes of the chambers 206 and the holes 208 may be used without departing from the scope of this disclosure. For example, the chambers 206 and/or the holes 208 may have any polygonal or round cross-section and any combination thereof. Equations for chamber heights may be derived similar to those above. Furthermore, the broadband acoustic metasurface 102 may contain chambers 206 and/or holes 208 with the same cross-section or different cross-sections. In other words, the shapes of the chambers 206 and/or the holes 208 need not be similar within a group or within the broadband acoustic metasurface 102.

### Height Variance

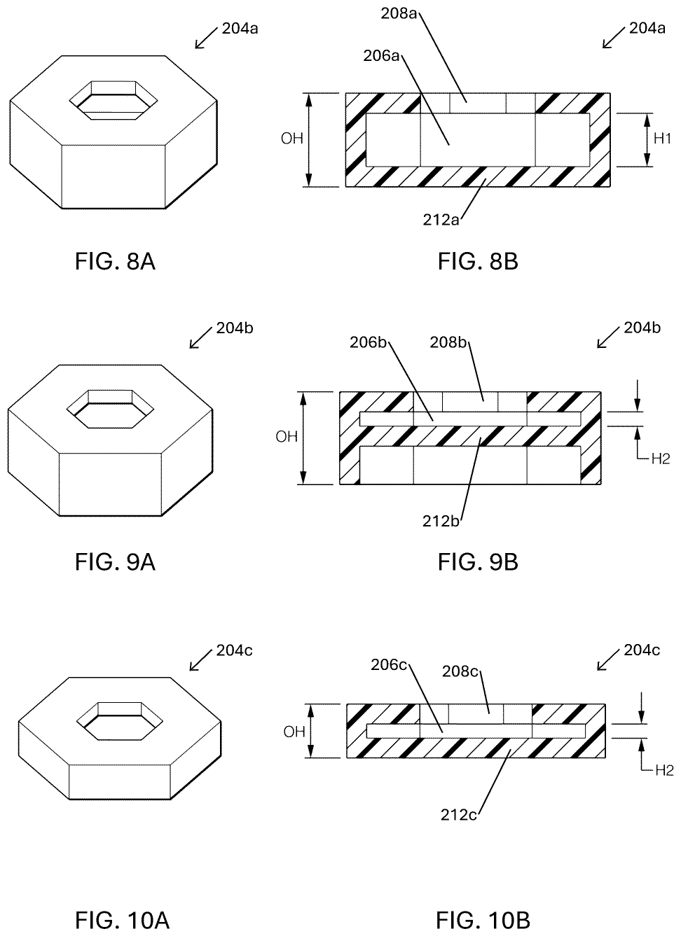

In order to achieve the varying chamber heights H of the chambers 206 (e.g., to form the broadband acoustic metasurface 200), the cells 204 and/or the body 202 may be configured in a variety of ways. For example, FIG. 8A illustrates a cell 204a, and FIG. 8B illustrates a cross section of the cell 204a. FIG. 9A illustrates a cell 204b, and FIG. 9B illustrates a cross section of the cell 204b. FIG. 10A illustrates a cell 204c, and FIG. 10B illustrates a cross section of the cell 204c.

The chamber 206a of the cell 204a has a chamber height H1. The chamber 206b of the cell 204b and the chamber 206c of the cell 204c both have a chamber height H2. Height H2 is different (e.g., smaller) than height H1. Accordingly, the cell 204b and the cell 204c have a different (e.g., higher) attenuation frequency than that of the cell 204a.

To realize the chamber height difference between the chamber 206a and the chamber 206b, an overall height (e.g., marked as dimension “OH”) of cell 204a and cell 204b is the same, but the floor 212b is closer to the hole 208b than the floor 212a is to the hole 208a. Chamber height H1 may be a maximum chamber height of the broadband acoustic metasurface 102 (e.g., due to the floor 212a being flush with ends of the side walls of the cell 204a). Assuming the other dimensions are the same, the higher floor (e.g., floor 212b) causes the height H2 to be less than H1. Thus, cell 204a has a different attenuation frequency than cell 204b. When cell 204a and cell 204b are placed and/or formed adjacent to each other, the overall heights are the same (assuming the respective top surfaces are flush).

FIG. 10 and FIG. 10B illustrate another way to realize the chamber height difference. To realize the height difference between the chamber 206a and the chamber 206c, the overall height of cell 204c is different (e.g., less) than the overall height of cell 204a. Assuming the other dimensions are the same, the reduced overall height causes the chamber height H2 to be less than chamber height H1. When cell 204a and cell 204c are placed and/or formed adjacent to each other, the respective top surfaces may be flush, the respective bottom surfaces may be flush, or there may be an offset therebetween.

Looking at FIGS. 8A, 8B, 9A and 9B, by keeping the overall height the same, a top surface of the broadband acoustic metasurface 102 may remain flat (see FIG. 2A), and the body 202 may have a constant overall thickness across the cells 204 (e.g., due to walls between the chambers 206 having a constant height throughout). Doing so may allow for good airflow (e.g., due to less turbulence), attenuation of multiple frequencies (e.g., due to no eddy currents), and stability of the broadband acoustic metasurface 102 (e.g., because the wall heights are the same length and, thus, the broadband acoustic metasurface may not be wobbly).

It should be noted that the broadband acoustic metasurface 102 may be formed by a combination of the configurations above. For example, a portion of the broadband acoustic metasurface 102 may have constant overall heights with different chamber heights H, and another portion of the broadband acoustic metasurface 102 may have varying overall heights with different chamber heights H. To save on material cost and/or manufacturing cost, constant overall heights may be implemented on cells 204 of corners and/or cells 204 around a border of the broadband acoustic metasurface 102, and varying overall heights may be implemented on cells 204 within an interior of the broadband acoustic metasurface 102.

### Example Configurator

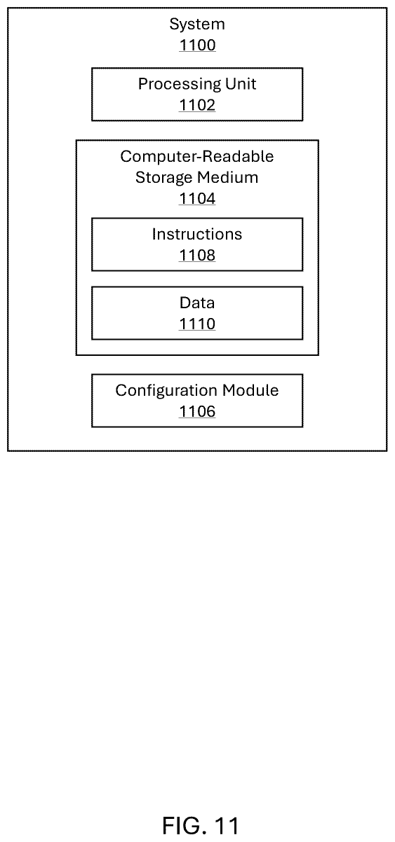

FIG. 11 illustrates an example of a system 1100 that may be used for determining a configuration of the broadband acoustic metasurface 102. Specifically, the system 1100 may be used to determine dimensions of the cells 204, including chamber heights of the chambers 206. The system 1100 includes at least one processing unit 1102, at least one computer-readable storage medium 1104, and a configuration module 1106.

The processing unit 1102 (e.g., one or more of an application processor, central processing unit (CPU), graphics processing unit (GPU), microprocessor, digital-signal processor (DSP), or controller) executes instructions 1208 (e.g., code) stored within the computer-readable storage medium 1104 (e.g., a non-transitory storage devices such as a hard drive, solid-state drive (SSD), flash memory, random access memory (RAM), read-only memory (ROM), erasable programmable read-only memory (EPROM), or electrically erasable programmable read-only memory (EEPROM)) to cause the system 1100 to determine one or more configurations of a broadband acoustic metasurface. The instructions 1108 may be part of an operating system and/or one or more applications of the system 1100.

The instructions 1108 cause the processing unit 1102 to act upon (e.g., create, receive, modify, delete, transmit, or display) the data 1110 (e.g., application data such as design constraints). Although shown as being within the computer-readable storage medium 1104, portions of the data 1110 may be within a random-access memory (RAM) or a cache of the system 1100 (not shown). Furthermore, the instructions 1108 and/or the data 1110 may be remote to the system 1100.

The configuration module 1106 (or portions thereof) may be comprised by the computer-readable storage medium 1104 or be a stand-alone component (e.g., executed in dedicated hardware in communication with the processing unit 1102 and computer-readable storage medium 1104). For example, the instructions 1108 may cause the processing unit 1102 to implement or otherwise cause the configuration module 1106 to determine the configuration of the broadband acoustic metasurface 102.

The system 1100 may also contain a communication system (not shown) that may be any wired or wireless communication system configured to communicate data over one or more connections or networks. For example, the communication system may be configured to communicate data between the system 1100 and a separate device (e.g., a manufacturing device configured to produce the broadband acoustic metasurface 102).

Returning to the configuration module 1106, the configuration module 1106 may be configured to receive inputs (e.g., design constraints) corresponding to a configuration of the broadband acoustic metasurface 102. The inputs may come from a user of the system 1100 (e.g., via a graphical user interface (GUI)). For example, the configuration module 1106 may receive a plurality of target frequencies (e.g., center frequencies). It should be recognized that each target frequency will have a corresponding group of one or more cells 204. Thus, if 6 target frequencies are received, then the broadband acoustic metasurface will have 6 groups of cells 204. The inputs may also comprise a severity level for each of the target frequencies (e.g., to rank or determine respective amounts of attenuation).

The configuration module 1106 may also receive space constraints. For example, the configuration module 1106 may receive a maximum length, maximum width, maximum height or thickness, etc. The space constraints may correspond to a target installation location of the broadband acoustic metasurface.

The configuration module 1106 may also receive information about cell configuration or dimensions. For example, the configuration module 1106 may receive a shape of the cells 204 (e.g., the shape of the chambers 206), a shape of the holes 208, a cross-sectional size of the cells 204 (e.g., a cross-sectional size of the chambers 206), a length of the holes 208, a cross-sectional size of the holes 208, wall, ceiling, and/or floor thickness, etc.

The configuration module 1106 may use the target frequencies along with other constraints and/or constants (e.g., fixed dimensions of the cells 204) to determine respective chamber heights of the chambers 206. For example, the configuration module 1106 may use Equation 2 to determine chamber heights for a plurality of attenuation frequencies (assuming the other dimensions of the cells 204 remain constant). From there, the configuration module 1106 may produce one or more configurations of the broadband acoustic metasurface 102 (e.g., layout of cells 204, size of cells 204, etc.). For example, the configuration module 1106 may produce a plurality of configurations such that a user may select one for implementation and/or fabrication/manufacturing.

As discussed above, groups with adjacent attenuation frequencies need not be adjacent. In some implementations, however, the configuration module 1106 may arrange the groups such that neighboring groups have neighboring attenuation frequencies. For example, the configuration module 1106 may be configured to arrange the cells 204 such that the groups, in one or more directions, go from lowest to highest attenuation frequency or visa-versa.

The configuration module 1106 may also be configured to maximize a total volume (e.g., of all the cells 204) of the broadband acoustic metasurface 102 while still adhering to the space constraints. Doing so may enable the broadband acoustic metasurface 102 to have maximum attenuation in the space provided.

The configuration module 1106 may be configured to output the configuration (e.g., one or more chamber dimensions, one or more hole dimensions, one or more cell dimensions, one or more body dimensions, etc.). The configuration module 1106 may also be configured to output the configuration as a model or other file format (e.g., computer-aided design (CAD) file, parametric model, computer-aided manufacturing (CAM) file, table, list, etc.) such that the broadband acoustic metasurface can be produced. For example, the configuration module 1106 may output the selected configuration as a file usable by a 3D printer to 3D print the broadband acoustic metasurface. The configuration module 1106 may also interface with a design software (e.g., CAD, parametric modeler, etc.) to create a model for manufacturing. In such cases, the configuration module 1106 may act as a plug in, macro, or the like.

Regardless of how it is implemented, the configuration module 1106 is configured to determine a configuration of a broadband acoustic metasurface 102 based on a set of inputs. In this way, the configuration module 1106 may enable effective broadband acoustic metasurfaces to be designed for many different environments (e.g., frequencies and/or locations) quickly and easily.

### Example Active Cells

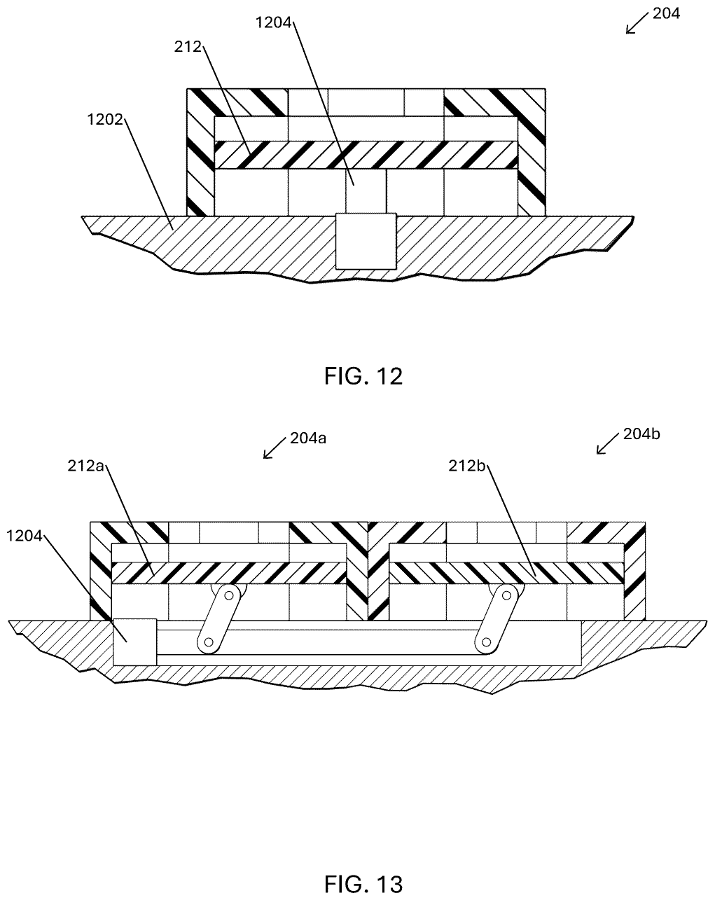

FIGS. 12 and 13 illustrate example active cells. Active cells, as used herein, refers to cells 204 that have floors 212 that are not fixed relative to the rest of the cells 204. For example, looking at FIG. 12, a cell 204 may have a floor 212 that is connected to an external structure 1202 via an actuator 1204. Assuming that the rest of the cell 204 is stationary (e.g., secured to the external structure 1202), the actuator 1204 can move the floor 212 up and down within the cell 204, effective to vary the chamber height H and, thus, the attenuation frequency of the cell 204. Using the example dimensions above with reference to FIG. 5, the actuator 1204 may be configured to move the floor 212 a span of 0.212 inches to allow for chamber heights H between 0.260 inches and 0.048 inches. Doing so allows the cell 204 to achieve target attenuation frequencies anywhere between 3000 Hz and 7000 Hz.

Although the actuator 1204 is shown coupled with the external structure 1202, the actuator 1204 may also be coupled with the rest of the cell 204 (e.g., other than the floor 212) and/or the body 202. There may also be one or more intermediate components (e.g., reduction gears, levers, linkages, etc.) between the actuator 1204 and the floor 212. Regardless of implementation, the actuator 1204 is configured to move the floor 212 relative to the rest of the cell 204. It should be noted that active cells may be mixed with inactive cells (e.g., cells 204 with floors 212 that are fixed).

FIG. 13 is similar to FIG. 12, except that the actuator 1204 is coupled with two floors (e.g., floor 212a and floor 212b of cell 204a and cell 204b, respectively). For example, cell 204a and cell 204b may belong to a same group (e.g., configured to have the same attenuation frequency via the same chamber height). By coupling the floors 212 together with a single actuator, components and/or cost may be reduced. Furthermore, control (as discussed below) may be easier. Any number of cells 204 may be linked to the actuator 1204.

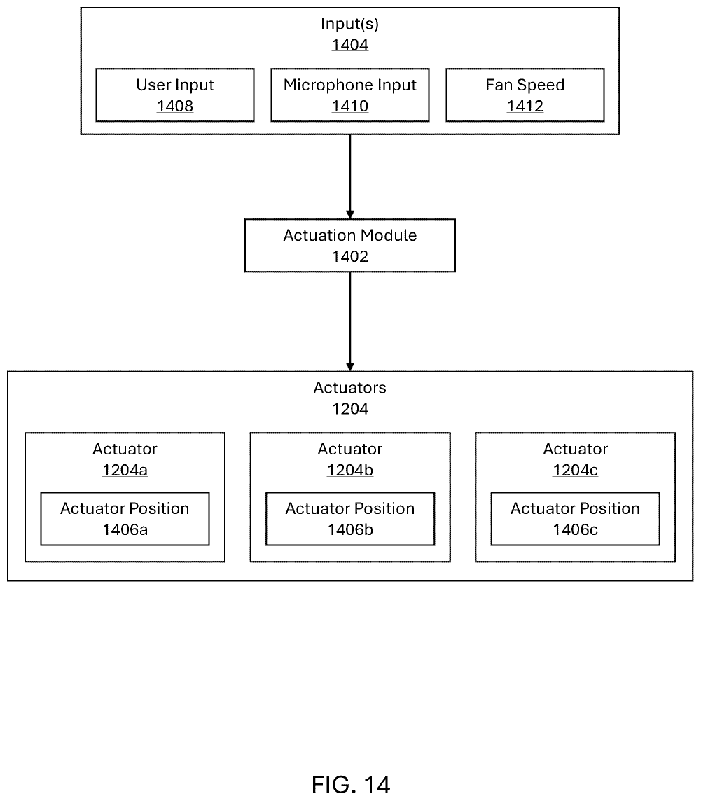

FIG. 14 illustrates an example flow of configuring the broadband acoustic metasurface 102 when it has active cells. An actuation module 1402 receives one or more inputs 1404 and determines actuator positions 1406 for one or more actuators 1204 coupled with floors 212 of a broadband acoustic metasurface 102. The actuator positions 1406 correspond to desired chamber heights for the active cells (e.g., based on relationships therebetween). For example, based on the inputs 1404, the actuation module 1402 may determine an actuator position 1406a for actuator 1204a (corresponding to a first desired chamber height for one or more cells 204 coupled with the actuator 1204a), an actuator position 1406b for actuator 1204b (corresponding to a second desired chamber height for one or more cells 204 coupled with the actuator 1204b), and an actuator position 1406c for actuator 1204c (corresponding to a third desired chamber height for one or more cells 204 coupled with the actuator 1204).

Groups of active cells may receive actuator positions 1406 that are the same. For example, the actuator 1204a may correspond to a first group, the actuator 1204b may correspond to a second group, and the actuator 1204c may correspond to a third group, all with varying attenuation frequencies. Any number of actuators 1204 may be used for each of the groups. As an example, each active cell may have an actuator 1204 coupled thereto. As such, an actuator position 1406 may be used by a plurality of actuators 1204 of the group. If cells 204 are linked, however (e.g., as in FIG. 13), then an actuator 1204 may control a plurality of cells 204.

The inputs 1404 may include one or more of: a user input 1408, a microphone input 1410, or a fan speed 1412. The user input 1408 may correspond to desired chamber heights (e.g., from the configuration module 1106 or elsewhere), desired attenuation frequencies, relative frequency importance (e.g., to cause a group to have more cells than another group), or some other desired characteristics of the active cells.

The microphone input 1410 may correspond to noise characteristics of an environment. For example, when the broadband acoustic metasurface 102 is disposed within the server 100 and the server 100 is in operation, a microphone may be implemented to determine frequencies and amplitudes of noise to be attenuated. The actuation module 1402 may determine attenuation frequencies for a plurality of groups of cells 204 based on the microphone input 1410. The actuation module 1402 may determine frequencies with the highest amplitudes, evenly partition one or more bands of frequencies, or target various frequencies (e.g., based on human hearing) for the cells 204. As discussed above, numbers of cells within the groups may vary between groups and frequency spacing between the groups may also vary (e.g., there may be frequency bands that are not targeted for attenuation, and those bands may vary in width).

The fan speed 1412 corresponds to a speed of the fans 104 within the server 100. Each of a plurality of fan speeds may have unique noise characteristics. Thus, by knowing the noise produced at each fan speed, the actuation module 1402 can determine attenuation frequencies (and amplitudes for numbers of cells 204 within the groups) for the broadband acoustic metasurface 102. For example, the actuation module 1402 may use a look-up table to determine appropriate frequencies and/or actuator positions 1406 based on the fan speed 1412.

Other inputs may also be used by the actuation module 1402 to determine attenuation frequencies. Regardless of what inputs are used, the actuation module 1402 determines actuator positions 1406 for a plurality of actuators 1204 (e.g., based on desired chamber heights corresponding to respective attenuation frequencies) and causes the actuators 1204 to assume the actuator positions 1406.

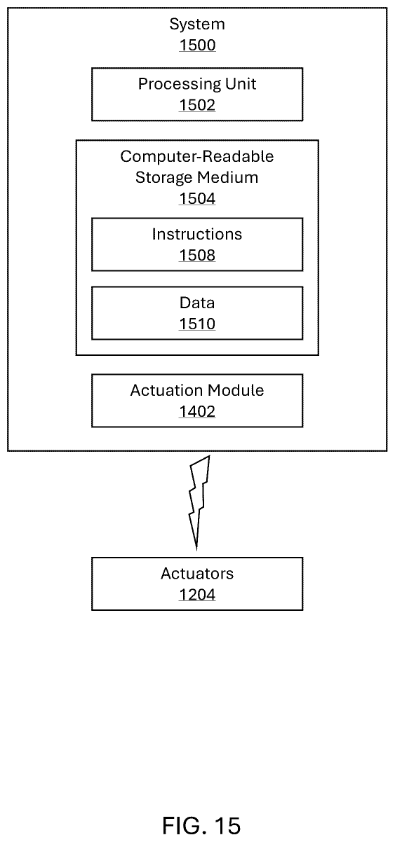

FIG. 15 illustrates an example of a system 1500 that may be used for configuring active cells of the broadband acoustic metasurface 102. Specifically, the system 1500 may be used to configure chamber heights of the chambers 206 via the actuators 1204. The system 1500 may be different or the same as the system 1100. For example, the system 1500 may be part of a baseboard management controller (BMC) or other infrastructure system of the server 100. The system 1500 includes at least one processing unit 1502, at least one computer-readable storage medium 1504, and the actuation module 1402.

The processing unit 1502 (e.g., one or more of an application processor, central processing unit (CPU), graphics processing unit (GPU), microprocessor, digital-signal processor (DSP), or controller) executes instructions 1208 (e.g., code) stored within the computer-readable storage medium 1504 (e.g., a non-transitory storage devices such as a hard drive, solid-state drive (SSD), flash memory, random access memory (RAM), read-only memory (ROM), erasable programmable read-only memory (EPROM), or electrically erasable programmable read-only memory (EEPROM)) to cause the system 1500 to determine actuator positions 1406 for a plurality of actuators 1204 of a broadband acoustic metasurface 102 and cause the actuators 1204 to assume the actuator positions 1406. The instructions 1508 may be part of an operating system and/or one or more applications of the system 1500.

The instructions 1508 cause the processing unit 1502 to act upon (e.g., create, receive, modify, delete, transmit, or display) the data 1510 (e.g., application data such as design constraints). Although shown as being within the computer-readable storage medium 1504, portions of the data 1510 may be within a random-access memory (RAM) or a cache of the system 1500 (not shown). Furthermore, the instructions 1508 and/or the data 1510 may be remote to the system 1500.

The actuation module 1402 (or portions thereof) may be comprised by the computer-readable storage medium 1504 or be a stand-alone component (e.g., executed in dedicated hardware in communication with the processing unit 1502 and computer-readable storage medium 1504). For example, the instructions 1508 may cause the processing unit 1502 to implement or otherwise cause the actuation module 1402 to configure the active cells of the broadband acoustic metasurface 102.

The system 1500 may also contain a communication system (not shown) that may be any wired or wireless communication system configured to communicate data and/or signals over one or more connections or networks. For example, the communication system may be configured to communicate data between the system 1500 and the actuators 1204. There may be one or more intermediate devices (e.g., motor controller, positions controller, actuator controller) disposed between the system 1500 and the actuators 1204.

It should be noted that, the grouping and/or order of the cells 204 configured by the actuation module 1402 may not be significant. In other words, as discussed above, groups with adjacent attenuation frequencies need not be adjacent. In some implementations, however, the actuation module 1402 may arrange the actuator positions 1406 such that neighboring groups have neighboring attenuation frequencies. For example, the actuation module 1402 may be configured to arrange the actuator positions 1406 such that the groups, in one or more directions relative to the broadband acoustic metasurface 102, go from lowest to highest attenuation frequency or visa-versa.

### EXAMPLES

Example 1: A broadband acoustic metasurface configured to be disposed within or proximate a server, the broadband acoustic metasurface comprising: a body forming: a plurality of chambers having respective volumes; and a plurality of holes in communication with the chambers and configured to be in communication with moving air within or around the server.

Example 2: The broadband acoustic metasurface of example 1, wherein the chambers have polygonal cross-sections.

Example 3: The broadband acoustic metasurface of example 2, wherein the chambers have hexagonal cross-sections.

Example 4: The broadband acoustic metasurface of example 2 or 3, wherein the holes have polygonal or round cross-sections.

Example 5: The broadband acoustic metasurface of any of examples 1-4, wherein: the body forms a top surface; and the holes are in communication with the top surface.

Example 6: The broadband acoustic metasurface of any of examples 1-5, wherein the chambers have similar cross-sections along respective longitudinal axes of the chambers.

Example 7: The broadband acoustic metasurface of example 6, wherein at least two of the chambers have different heights along their respective longitudinal axes.

Example 8: The broadband acoustic metasurface of example 7, wherein the chambers are separated into a plurality of zones each having one or more chambers with a certain height.

Example 9: The broadband acoustic metasurface of example 8, wherein at least one of the zones includes a plurality of chambers that are adjacent to one another.

Example 10: The broadband acoustic metasurface of example 9, wherein at least one of the zones includes a plurality of chambers that are disposed in a linear array.

Example 11: The broadband acoustic metasurface of example 8, wherein at least one of the zones includes chambers that are dispersed amongst chambers of other zones.

Example 12: The broadband acoustic metasurface of example 7, wherein the body forms a plurality of floors that form the respective chambers.

Example 13: The broadband acoustic metasurface of example 12, wherein the floors are movable effective to create different volumes within the chambers.

Example 14: The broadband acoustic metasurface of example 13, further comprising one or more mechanical devices or actuators configured to move the floors in an axial direction of the chambers.

Example 15: The broadband acoustic metasurface of example 14, wherein each of the mechanical devices or actuators is configured to move a plurality of floors.

Example 16: A system comprising: a broadband acoustic metasurface configured to be disposed within or proximate a server, the broadband acoustic metasurface including: a body forming: a plurality of chambers with respective movable floors; and a plurality of holes in communication with the chambers and configured to be in communication with moving air within or around the server; and a plurality of actuators configured to move the floors along respective longitudinal axes of the chambers.

Example 17: The system of example 16, wherein at least one of the actuators is configured to move a plurality of the floors.

Example 18: The system of example 16 or 17, wherein the chambers are disposed in a two-dimensional array.

Example 19: A system comprising: a processing unit configured to: determine heights of chambers of a broadband acoustic metasurface disposed within or proximate a server; and cause one or more actuators to position floors of the broadband acoustic metasurface such that that the chambers assume the determined heights.

Example 20: The system of example 19, wherein the processing unit is configured to determine the heights of the chambers based on a fan speed of the server.

Example 21: The system of example 19, wherein the processing unit is configured to determine the heights of the chambers based on microphone inputs.

Example 22. The system of example 21, wherein: the processing unit is configured to determine a plurality of frequencies with highest amplitudes; and the heights of the chambers are based on the determined frequencies.

Example 23. The system of any of examples 19-22, wherein the processing unit is part of a baseboard management controller.

Example 24: A method comprising: receiving design constraints corresponding to a broadband acoustic metasurface; determining respective volumes and/or heights for a plurality of chambers of the broadband acoustic metasurface based on the design constraints; determining one or more configurations of the broadband acoustic metasurface based on the design constraints; outputting one of the configurations.

Example 25: The method of example 24, wherein: the design constraints comprise a plurality of target frequencies; and the respective volumes or heights correspond to the target frequencies.

Example 26: The method of example 24, wherein: the design constraints comprise a range of frequencies; the method comprises breaking the range of frequencies into smaller ranges; and the respective volumes or heights correspond to center frequencies of the smaller ranges.

Example 27: The method of any of examples 24-26, wherein the design constraints comprise external dimensions of the broadband acoustic metasurface.

Example 28: The method of any of examples 24-27, wherein the design constraints comprise a shape and/or a size of cross sections of the chambers of the broadband acoustic metasurface.

Example 29: The method of any of examples 24-28, wherein the volumes or heights are divided into a plurality of zones.

Example 30: The method of example 29, wherein at least one of the zones includes more chambers than another of the zones.

Example 31: A system comprising a processing unit configured to perform the method of any of examples 24-30.

Example 32: A non-transitory computer-readable storage medium comprising instructions that, when executed by a processing unit, cause the processing unit to perform the method of any of examples 24-30.

Example 33: A method of configuring a broadband acoustic metasurface, the method comprising: receiving one or more inputs; determining, based on the inputs, chamber heights for a plurality of chambers of the broadband acoustic metasurface; determining, based on the chamber heights, respective actuator positions for a plurality of actuators coupled with floors of the chambers; and causing the actuators to assume the actuator positions such that the chambers assume the chamber heights.

Example 34: The method of example 33, wherein the inputs comprise a microphone input.

Example 35: The method of example 34, wherein the microphone input corresponds to an interior space within a server.

Example 36: The method of any of examples 33-35, wherein the inputs comprise a fan speed of one or more fans within a server.

Example 37: The method of any of examples 33-36, wherein the method is repeated at a predetermined time interval.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

The server may also include a power supply configured to supply power to various components within the server. The power supply may be configured to adapt or change incoming power (e.g., alternating current to direct current and/or stepping up or stepping down voltage). Furthermore, the power supply may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionality of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A broadband acoustic metasurface disposed within or proximate a server, the broadband acoustic metasurface comprising:
a body forming:
a plurality of chambers having respective volumes; and
a plurality of holes in communication with the chambers and configured to be in communication with moving air within or around the server.

2. The broadband acoustic metasurface of claim 1, wherein the chambers have a polygonal cross-section.

3. The broadband acoustic metasurface of claim 2, wherein the chambers have hexagonal cross-sections.

4. The broadband acoustic metasurface of claim 2, wherein the holes have a polygonal or round cross-section.

5. The broadband acoustic metasurface of claim 1, wherein:
the body forms a top surface; and
the holes are in communication with the top surface.

6. The broadband acoustic metasurface of claim 1, wherein the chambers have a same cross-section.

7. The broadband acoustic metasurface of claim 6, wherein at least two of the chambers have different chamber heights.

8. The broadband acoustic metasurface of claim 7, wherein:
the chambers are separated into a plurality of groups; and
each of the groups has one or more chambers with a same chamber height.

9. The broadband acoustic metasurface of claim 8, wherein at least one of the groups includes a plurality of the chambers that are adjacent to one another.

10. The broadband acoustic metasurface of claim 9, wherein at least one of the groups includes a plurality of the chambers that are disposed in a linear array.

11. The broadband acoustic metasurface of claim 8, wherein at least one of the groups includes one or more of the chambers that are interspersed amongst chambers of other groups.

12. The broadband acoustic metasurface of claim 7, wherein the body forms a plurality of floors that form the chambers.

13. A system comprising:
a broadband acoustic metasurface configured to be disposed within or proximate a server, the broadband acoustic metasurface including:
a body forming:
a plurality of chambers with floors that are not fixed; and
a plurality of holes in communication with the chambers and configured to be in communication with moving air within or around the server; and
a plurality of actuators configured to move the floors along respective longitudinal axes of the chambers.

14. The system of claim 13, wherein at least one of the actuators is configured to move a plurality of the floors.

15. The system of claim 13, wherein the chambers are disposed in a two-dimensional array.

16. A system comprising:
a processing unit configured to:
determine chamber heights for a plurality of chambers of a broadband acoustic metasurface disposed within or proximate a server; and
cause one or more actuators to position floors of the broadband acoustic metasurface such that that the chambers assume the chamber heights.

17. The system of claim 16, wherein the processing unit is configured to determine the chamber heights based on a fan speed of the server.

18. The system of claim 16, wherein the processing unit is configured to:
receive a microphone input; and
determine the chamber heights based on the microphone input.

19. The system of claim 18, wherein:
the processing unit is configured to determine a plurality of frequencies with highest amplitudes; and
the chamber heights are based on the frequencies.

20. The system of claim 16, wherein the processing unit is part of a baseboard management controller.
